(19) United States
(12) Patent Application Publication
(10) Pub. No.: US 2008/0242072 A1
(43) Pub. Date: Oct. 2, 2008

(54) PLASMA DRY ETCH PROCESS FOR METAL-CONTAINING GATES

(75) Inventors: Jinhan Choi, Frisco, TX (US); Hyesook Hong, Allen, TX (US); Donald S. Miles, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/691,114

(22) Filed: Mar. 26, 2007

(51) Int. Cl. H01L 21/3205; H01L 21/4763; H01L 21/461

(52) U.S. Cl. 438/592; 438/588; 438/706

(57) ABSTRACT

A method of manufacturing a semiconductor device. The method comprises forming a gate stack layer. The gate stack has an insulating layer on a substrate, a metal-containing layer on the insulating layer, a metal nitride barrier layer on the metal-containing layer, and a silicon-containing layer on the metal nitride barrier layer. The method also comprises patterning the gate stack layer. Pattering includes a plasma etch of the metal nitride barrier layer. The plasma etch has a chloride-containing feed gas and a physical etch component. The physical etch component includes a high-mass species having a molecular weight of greater than about 71 gm/mol.

### TECHNICAL FIELD

The disclosure is directed, in general, to semiconductor devices, and more specifically, to devices having a metal-containing gate and its method of manufacture for the integrated circuit.

### BACKGROUND

There is greater interest in the use of metal-containing gates as a replacement to polysilicon gates, because metal gates can eliminate charge carrier depletion effects. The manufacture of metal gate electrodes, however, becomes increasingly difficult as minimal device dimensions (e.g., the critical dimension) shrink to the sub-30 nanometer range. In particular, it is difficult to pattern certain metal gate structures without the device having an unacceptably high leakage current. Additionally, patterning may not provide good vertical profile control of the gate, and the resulting gate structures are prone to mechanical failure. Consequently, it is difficult to manufacture mechanically stable metal gates that meet the device's target gate dimensions.

Accordingly, what is needed is a method for manufacturing metal gates that address the drawbacks of the prior art methods and devices.

### SUMMARY

One embodiment of the disclosure is a method of manufacturing a semiconductor device. The method comprises forming a gate stack layer. The gate stack layer has an insulating layer on a substrate, a metal-containing layer on the insulating layer, a metal nitride barrier layer on the metal-containing layer, and a silicon-containing layer on the metal nitride barrier layer. The method also comprises patterning the gate stack layer. Pattering includes a plasma etch of the metal nitride barrier layer. The plasma etch has a chloride-containing feed gas and a physical etch component. The physical etch component includes a high-mass species having a molecular weight of greater than about 71 gm/mol.

Another embodiment of the method of manufacturing the semiconductor device comprises forming one or more transistors on or in the semiconductor substrate. At least one of the transistors has a gate that is manufactured by a process that includes depositing an insulating layer on the substrate, depositing a tungsten-containing layer on the insulating layer, depositing refractory metal-containing nitride barrier layer on the tungsten-containing layer and depositing a polysilicon layer on said tungsten-containing nitride layer. The process also comprises patterning the tungsten-containing metal nitride layer, including etching the tungsten-containing metal nitride layer using a plasma etch process having BCl₃, or Cl₂ and HBr.

Another embodiment of the disclosure is an integrated circuit. The integrated circuit comprises one or more transistors on or in a semiconductor substrate. At least one of said transistors has a gate that includes the above describe gate stack layer. A top lateral dimension of the refractory metal-containing nitride barrier layer is within 10 percent of a bottom lateral dimension of the refractory metal-containing nitride barrier layer.

### BRIEF DESCRIPTION OF DRAWINGS

The disclosure is described with reference to example embodiments and to accompanying drawings, wherein:

FIG. 1 presents a flow diagram of an example method of manufacturing a semiconductor device that includes the metal-containing gate of the present disclosure; and

FIGS. 2-7 illustrate various stages of manufacture of example semiconductor devices of the disclosure.

### DETAILED DESCRIPTION

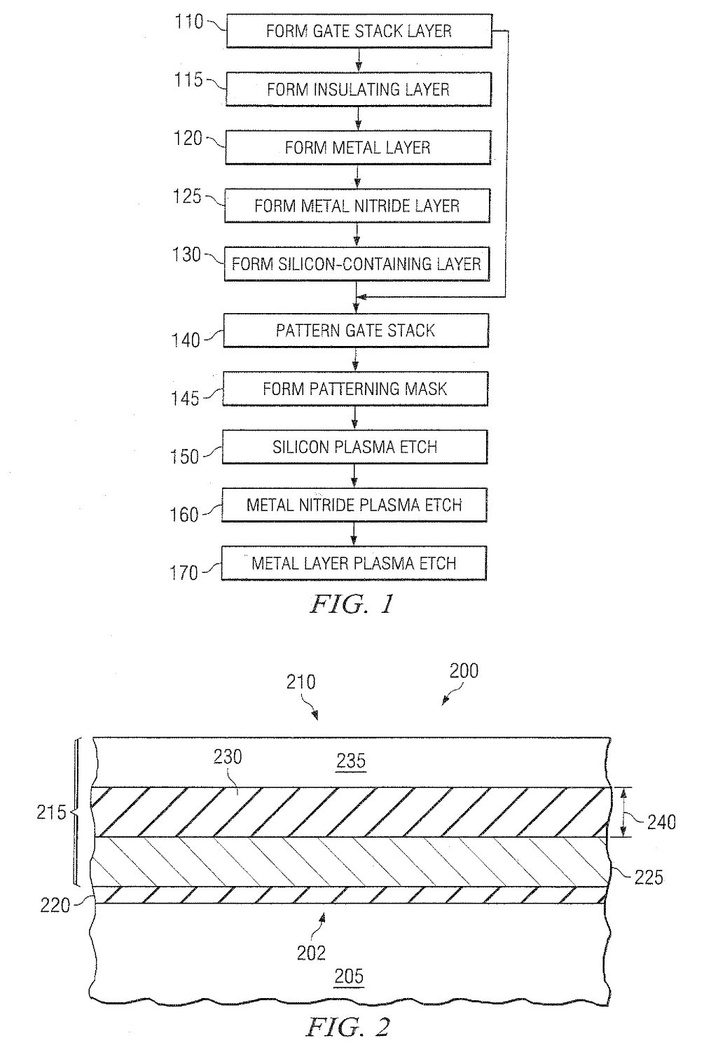

One aspect of the disclosure is a method of manufacturing semiconductor device that includes the fabrication of a metal-containing gate. FIG. 1 presents a flow diagram of an example method of manufacturing a semiconductor device that includes the metal-containing gate of the present disclosure.

The method includes forming a gate stack layer (step 110). Forming the gate stack layer 110 includes forming an insulating layer on a substrate (step 115), forming a metal-containing layer on the insulating layer (step 120), forming a metal nitride barrier layer on the metal layer (step 125), and forming a silicon-containing layer on the metal nitride barrier layer (step 130). E.g., embodiments of the gate stack layer have an insulating layer on a substrate, a metal-containing layer on the insulating layer, a metal nitride barrier layer on the metal layer, and a silicon-containing layer on the metal nitride barrier layer.

The method also includes patterning the gate stack layer (step 140). Patterning 140 can include forming a patterned mask over the gate stack layer (step 145), e.g., on the silicon-containing layer. The dimensions of the patterned mask correspond to the target dimensions (e.g., critical dimensions) of the patterned gate stack. Patterning the gate stack layer (step 140) can also include a silicon plasma etch of the silicon-containing layer (step 150). Patterning 140 can further include a plasma etch of the metal nitride barrier layer (step 160). E.g., the silicon-containing layer and the metal nitride barrier layer lying outside of the perimeter of the patterned mask are removed by the silicon etch 150 and the metal nitride plasma etch 160, respectively.

In some cases, the silicon plasma etch 150 includes oxygen as a feed gas. An oxygen-containing silicon plasma etch 150 can result in the formation of a metal oxide layer on a top surface of the metal nitride barrier layer. Cl₂ in the metal nitride plasma etch 160 can react with the metal oxide layer formed on the metal nitride barrier layer. The metal oxide and Cl₂ can react to form a non-volatile metal chloride on vertical walls of the partially etched metal nitride barrier layer. The metal chloride is more resistant to the metal nitride plasma etch 160 than the metal nitride. Consequently, the metal chloride can block the vertical etching of the metal nitride barrier layer by the metal nitride plasma etch. As result, a bottom lateral dimension of the patterned metal nitride barrier layer is substantially larger (e.g., greater than 10 percent) than its top lateral dimension. This, in turn, prevents the metal gate from having vertical walls and thereby prevents the target critical dimension for the device being met.

It was also discovered that when performing a metal nitride plasma etch 160 containing chlorine (Cl₂) only, the Cl₂ can diffuse through columnar crystal structures present in the metal nitride barrier layer and contact the underlying metal layer. The Cl₂ can etch holes, and in some cases pores, into the underlying metal layer before the metal nitride barrier layer is completely removed outside of a masked area. Consequently, when patterning the metal layer using a metal plasma etch (step 170), corresponding holes or pores can be etched into an underlying gate dielectric layer and the source and drain regions of the substrate. Excessive dopant penetration through these holes when forming the source and drain regions can lead to devices having a high off-leakage current. Electrical current can also punch through the holes or pores in the gate dielectric layer thereby increasing the leakage current.

The metal nitride plasma etch 160 of the disclosure obviates these problems by including a chloride-containing feed gas and a physical etch component. The physical etch component includes a high-mass species having a molecular weight of greater than about 71 gm/mol. The physical etch component is important, and in some cases critical, to successful gate fabrication. The physical etch component facilitates patterning of the gate stack so as to have a vertical profile. E.g., the physical etch component helped to prevent the build-up of chlorides on the side walls of the metal nitride barrier layer to have extensions (e.g., tails) that extend out beyond the perimeter of the patterned mask. E.g., in some embodiments of the patterned gate stack, a top lateral dimension of the patterned metal nitride barrier layer is within about 10 percent of a bottom lateral dimension of the patterned metal nitride barrier layer.

The inclusion of a chloride-containing feed gas in the metal nitride plasma etch 160, along with the physical component, is also important, and in some cases critical, to successful gate fabrication. The chloride-containing gas helps the plasma etch 160 to be selective towards the overlaying silicon-containing layer, and non-selective towards the metal nitride barrier layer. E.g., in some embodiments of the plasma etch 160, sufficient amounts of Cl-containing gas are included to ensure that the etch rate of the metal nitride barrier layer is at least about 10, and in some cases about 100, times greater than the etch rate of the silicon-containing layer. Excessive amounts of Cl-containing gas are to be avoided, however, because the Cl-containing gas can react with oxides to form the metal chloride tails on the vertical walls of the metal nitride barrier layer.

In some cases, the high-mass species of the metal nitride plasma etch 160 has a molecular weight ranging from about 81 (e.g., HBr) to 117 gm/mol (e.g., BCl₃). In some cases the metal nitride plasma etch 160 has a chloride-containing feed gas of Cl₂ and a physical etch component of HBr. In other cases, the chloride-containing feed gas and the physical etch component are both BCl₃. BCl₃ does not pass between columnar crystal structures of certain metal nitrides (e.g., TaN, TiN) as readily as low-mass species, or even Cl₂, and therefore is less prone to form holes or pores in the underlying metal layer. Additionally, BCl₃ is selective towards certain metal layers, and therefore does not readily etch the metal. E.g., in certain embodiments of the plasma etch 160 that use BCl₃, a metal nitride layer of TaN or TiN is etched at least about 10, and in some cases about 100, times faster than the underlying metal layer or tungsten or tungsten silicide. Being selective for the underlying metal also facilitate the ability of BCl₃ to etch the metal nitride layer laterally (e.g. parallel with the substrate surface) and thereby prevent the build-up of metal chloride tails on the sideways of the patterned metal nitride barrier layer.

As part of the present disclosure, it was found that that a physical etch component of low-mass species (e.g., H₂, He, Ar) is ineffective at facilitating the formation of vertical gate stack profiles and uniform removal of the metal nitride barrier layer. E.g., in some embodiments of the metal nitride plasma etch 160, the physical etch component consists essentially of the high-mass species. E.g., there are no significant quantities (less than about 1 mol percent) of lower-mass species having a molecular weight of less than about 71 gm/mol (e.g., H₂, He, Ar). In some cases, such low-mass species can diffuse between the columnar structures of certain metal nitrides (e.g., TaN or TiN) thereby etch holes or pores into the underlying metal layer. In some cases, however, the inclusion of such low-mass species may improve the selectively of the plasma etch 160. In such cases, sufficient amounts of the physical etch component can be included in the plasma etch 160 to allow uniform metal nitride barrier layer removal without hole or pore formation.

As noted above, the metal oxide layer can react with the etchants of metal nitride plasma etch 160 to form a metal chloride residue on vertical walls of the patterned metal nitride barrier layer. The inclusion of a high-mass species like BCl₃ or HBr as the physical component of the plasma etch 160 helps to prevent the build-up of the metal chloride. In some embodiments the vertical walls of the patterned metal nitride barrier layer after the plasma etch are substantially free of metal chloride. E.g., there is no metal chloride layer visible in transmission electron microscope images of the gate stack.

The physical etch component also facilitates the uniform removal of the metal nitride barrier layer, without forming holes in the underlying metal layer. The physical etch component of the metal nitride plasma etch 160 facilitate the uniform removal of the metal nitride barrier layer, thereby reducing the surface roughness of the underlying metal layer. E.g., during or immediately after the plasma etch process, the surface roughness equals about 2 nm (3 sigma) or less as measured by atomic force microscope (AFM). This follows because, unlike a Cl₂-only plasma etch 160, the physical etch component of the plasma etch 160 of the disclosure does not substantially pass through the columnar structures of the metal nitride barrier layer or etch the pattern of columnar structures into the underlying metal-containing layer. The resulting low surface roughness of the underlying metal layer, in turn, helps to reduce the surface roughness and punch-through in the underlying insulating layer and in the substrate itself. That is, the metal layer plasma etch 170 does not introduce holes and pores into the insulating layer and in the substrate. E.g., for some embodiments of the source and drain regions of the substrate, following gate stack layer patterning 140, has a surface roughness equal to about 0.3 nm (3 sigma by AFM) or less.

To further illustrate aspects of the disclosure, FIGS. 2-7 show cross-section views, at various stages of manufacture, of an example semiconductor device 200 according to the principles of the present disclosure. In some cases, the device 200 includes a transistor 202 having a gate 210 that is manufactured according to embodiments of the disclosure (FIG. 2). E.g., one or more transistors 202 are formed on or in a semiconductor substrate 205 (e.g., silicon wafer), and at least one of the transistors 202 has a gate 210 that is manufactured by a process of the disclosure.

With continuing reference to FIG. 1, FIG. 2 shows the device 200 after forming a gate stack layer 215 in accordance with step 110. E.g., an insulating layer 220 (e.g., silicon oxide or a high k-dielectric such as hafnium dioxide) can be deposited on the substrate 205 in accordance with step 115, Chemical vapor deposition (CVD), physical vapor deposition (PVD), atomic layer deposition (ALD), or other conventional methods can be used to accomplished the deposition. Similar techniques can be used to deposit a metal-containing layer 225 (e.g., a refractory metal or, silicides thereof such as a tungsten-containing layer like tungsten or tungsten silicide) on the insulating layer 220 (step 120), and a metal-containing nitride barrier layer 230 (e.g., TaN or TiN or other refractory metal nitrides) on the metal-containing layer 225 (step 125). A silicon-containing layer 235 (e.g., polysilicon) can be deposited on the metal nitride barrier layer 230 using PVD, CVD, or ALD (step 130).

The metal nitride layer 230 is configured to act as a barrier layer to prevent the inter-diffusion of atoms between the silicon-containing layer 235 and the metal-containing layer 225. E.g., the metal nitride layer 230 acts a barrier to prevent tungsten atoms from a tungsten-containing metal layer 225 diffusing into the silicon-containing layer 235. Additionally the metal nitride layer 230 acts as a barrier to prevent oxygen atoms from the silicon-containing layer 235 from diffusing into the metal-containing layer 225. The inter-diffusion of such atoms can change the gate's work-function from its intended value. To facilitate serving as a barrier layer, in some embodiments, the metal nitride layer 230 has a thickness 240 of at least about 10 nm.

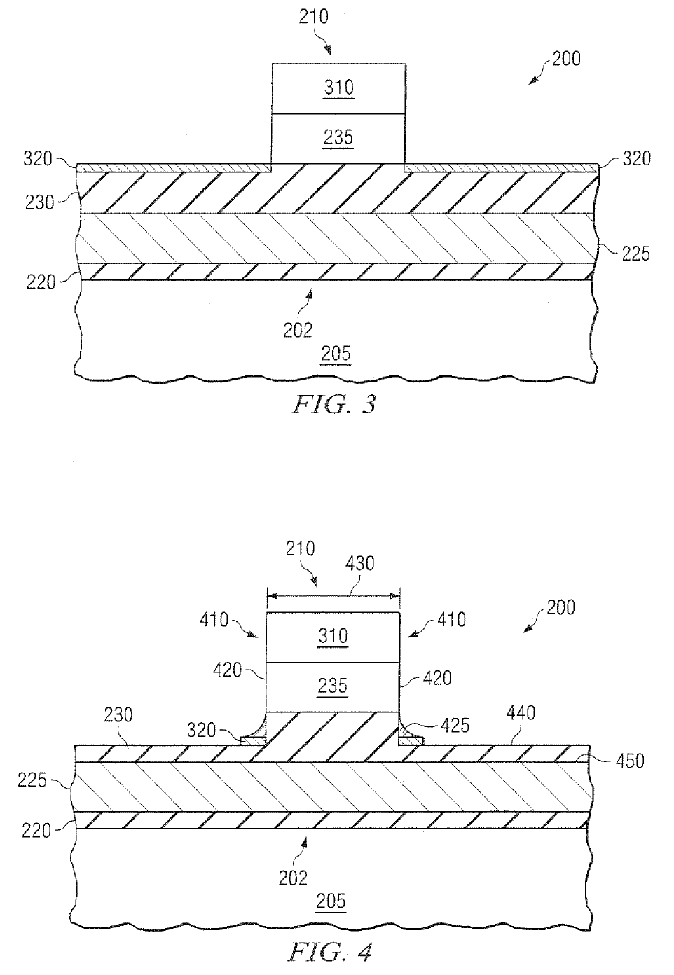

FIGS. 3-6 show the device 200 at different stages of patterning the gate stack layer 215 (FIG. 2) in accordance with step 140. FIG. 3 shows the device after forming a patterned mask 310 on the gate stack layer 215 (FIG. 2, FIG. 1 step 145). E.g., a hard mask material such as silicon dioxide, silicon oxynitride, silicon nitride can be deposited (e.g., tetra-ethoxy-silane by CVD) on a polysilicon layer 235 and then patterned using conventional photolithography techniques. FIG. 3 also shows the device 200 after patterning the silicon-containing layer 235 (step 150). In some cases, the silicon plasma etch uses an oxygen-containing plasma. E.g., a patterned polysilicon layer 235 can be formed with a plasma etch using feed gases that includes halogen atoms (Cl₂, HBr, CF₄, NF₃, or mixtures thereof) and oxygen (O₂). As further illustrated in FIG. 3, in embodiments where the silicon plasma etch uses an oxygen-containing plasma, a top portion of the metal-containing nitride layer 230 can be converted into a metal oxide layer 320. E.g., a tungsten nitride layer 230 can be partially converted into a tungsten oxide layer 320 during the silicon plasma etch.

FIG. 4 shows the device 200 during patterning the metal-containing nitride layer 230 using a plasma etch process having a chloride-containing feed gas and a physical etch component (step 160). In some embodiments, e.g., a tungsten-containing metal nitride layer 230 is etched using a plasma etch process having a BCl₃, Cl₂ and HBr, or a combination thereof. E.g., in some cases, the plasma etch process includes a feed gas of about 40 to 60 sccm BCl₃, a substrate temperature of about 50 to 80° C., a pressure of about 3 to 7 mTorr, an RF-power of about 900 to 1200 Watts and a duration of about 10 to 20 seconds. In other cases, the plasma etch process includes a feed gas of about 20 to 40 sccm HBr and about 15 to 30 sccm Cl₂, a substrate temperature of about 50 to 80° C., a pressure of about 3 to 7 mTorr, an RF-power of about 900 to 1200 Watts and duration of about 10 to 20 second.

FIG. 4 shows tails 410 extending from the vertical walls 420 of the partially etched metal-containing nitride layer 230. The tails 410 can comprise portions of the metal oxide layer 320 and metal chloride 425 that is formed from the metal oxide layer 320 during the plasma etch process 160. As noted above, however, the physical etch component of the plasma etch process 160 helps to prevent excessive build up of the tails 410.

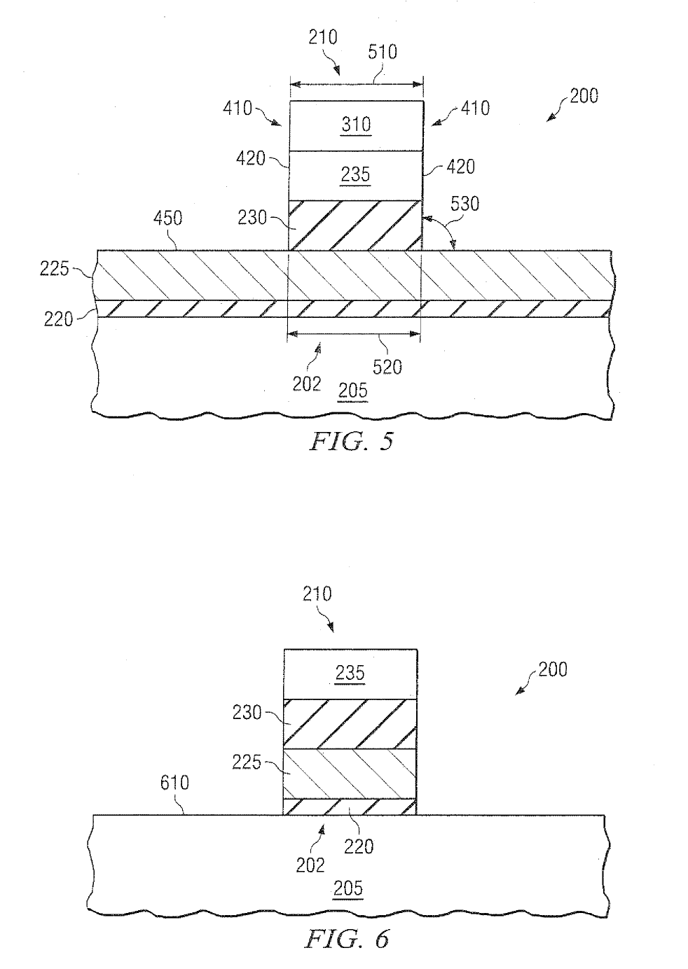

As illustrated for the example embodiment depicted in FIG. 4, the metal-containing nitride layer 230 lying outside of a perimeter 430 of the patterned mask 310 is uniformly removed by the plasma etch process 160. E.g., at any period during the metal nitride plasma etch process 160, a surface 440 of the metal-containing nitride layer 230 has a roughness of about 4 to 5 nm (3 sigma by AFM) or less. A surface 450 of the underlying metal-containing layer 225 also has a roughness of about 2 nm (3 sigma by AFM) or less both during (FIG. 4) or immediately after the plasma etch process (FIG. 5).

FIG. 5 shows the device 200 at the completion of the plasma etch process 160. The patterned metal-containing nitride layer 230 has substantially vertical walls 420. E.g., a top lateral dimension 510 of the patterned refractory metal-containing nitride barrier layer 230 is within about 10 percent of a bottom lateral dimension 520. In some embodiments the vertical walls 420 form an angle 530 with respect to a lateral surface 450 of the metal layer 225 that ranges from about 89 to 90 degrees.

FIG. 6 shows the device 200 after patterning the metal-containing layer 225 in accordance with step 170. E.g., a metal-containing layer 225 comprising tungsten or tungsten silicide can be etched using a plasma etch process 170 comprising about 80:80:20 (sccm ratios) Cl₂:He:O₂ at a chamber pressure of about 5 mTorr, an RF-power (top power source) of about 350 Watts and about bottom RF source of about 70 Volt, at about 60° C. for about 15 seconds.

The uniform removal of the metal nitride layer 230, giving rise to a smooth metal-containing layer 225 surface 450 (FIG. 4) also helps to keep the substrate 205 smooth. This follows because holes or pores are not formed in the metal-containing layer 225 during its removal. This helps to prevent etchants of the metal-containing layer 225 from penetrating through the holes or pores to etch away portions of the substrate's 205 surface 610 during the metal plasma etch 170. E.g., in some embodiments following the metal plasma etch 170, the substrate surface 610 a roughness of about 0.5 nm (3 sigma by AFM) or less.

FIG. 6 also presents the device 200 after removing the patterned mask 310 and insulating layer 220 (FIG. 5) that was not covered by the patterned layers 225, 230, 235 of the gate 210. E.g., a patterned mask 310 and insulating layer 220 both comprising silicon dioxide can be removed in a wet etch comprising an aqueous solution of hydrofluoric acid and ammonium fluoride. However, in other embodiments, of the patterned mask 310 or insulating layer 220 may be left on.

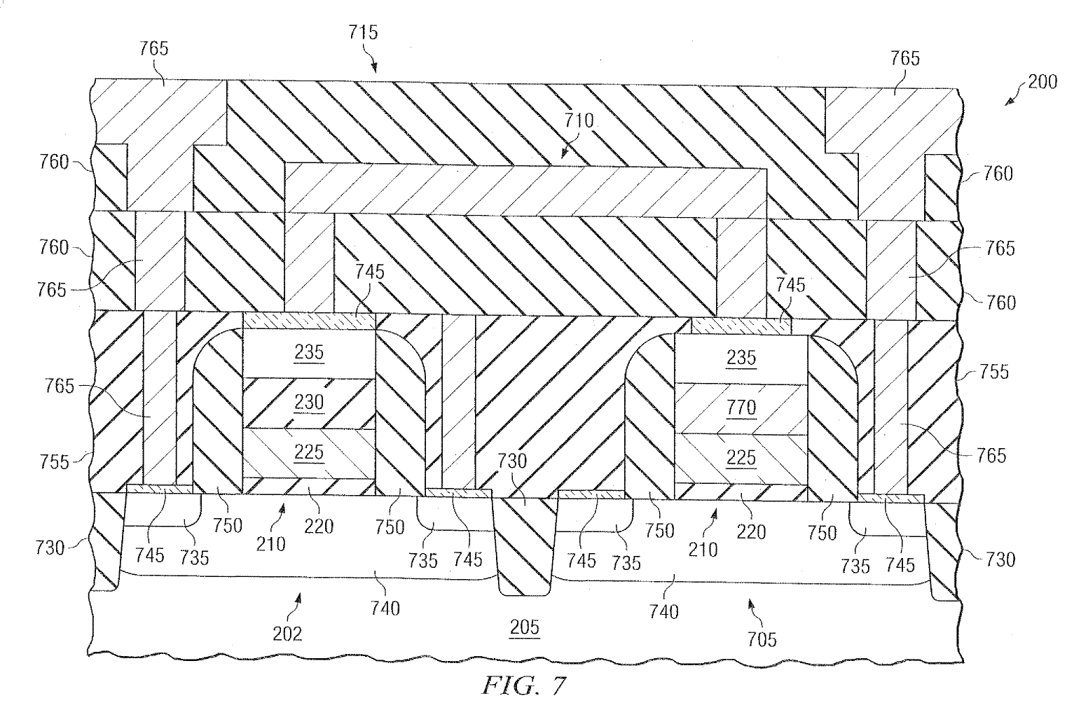

FIG. 7 shows the example device 200 after forming one or more transistors 202, 705 on or in the substrate 205. At least one of the transistors 202 is manufactured by an embodiment of the method discussed above in the context of FIGS. 1-6. In some cases, a plurality of transistors 202, 705 are made using the same or alternative embodiments of the method. In some cases at least one of the transistors 202, 705 is a metal oxide semiconductor (MOS) transistor. E.g., one transistor 202 can be a pMOS transistor, while another transistor 705 can be an nMOS transistor. The transistors 202, 705 can be coupled to each other to form a complementary MOS (CMOS) device 710. In some cases the device 200 includes, or is, an integrated circuit (IC) 715 having the transistor 202, or the transistors 202, 705.

Numerous additional steps can be performed before or after the processes described above in the context of FIGS. 1-6 to complete the manufacture of the transistor 202. E.g., isolation structures 730 can be formed in the substrate 205 and the substrate 205 can be implanted with dopants to form source and drain regions 735, and doped wells 740 in the substrate 205. Metal silicide contacts 745 can be formed on the source and drain regions 735 and gate 210. The gate 210 can also be implanted with dopants to adjust its work function, and sidewall structures 750 can be formed on the gate 210. A pre-metal dielectric (PMD) layer 755 can be deposited over the transistor 202 (or transistors 202, 705), and inter-layer dielectric (ILD) layers 760 deposited over the PMD layer 755. Both the PMD and ILD layers 755, 760 can comprise silicon dioxide, tetra-ethyl-ortho-silicate or other insulators. Interconnects 765 can be formed through the PMD and ILD layers 755, 760 to interconnect the transistor 202 to other transistors 705 of the IC 715.

FIG. 7 also illustrates another embodiment of the disclosure, an IC 715. The IC 715 comprises a transistor 202 on or in a semiconductor substrate 205. The transistor 202 has a gate 210 located on the substrate 205. The gate 210 includes an insulating layer 220 on the substrate 205, a metal-containing layer 225, a refractory metal-containing nitride barrier layer 230 on the metal-containing layer 225, and a silicon-containing layer 235 on the refractory metal-containing nitride barrier layer 230. A top lateral dimension 510 of the refractory metal-containing nitride barrier layer 230 is within 10 percent of a bottom lateral dimension 520 of the same layer 235 (FIG. 5).

In some embodiments, the metal-containing layer 225 includes a refractory metal and the metal nitride barrier layer 230 includes the same refractory metal. E.g., when the metal-containing layer 225 comprises W or WSi, the metal nitride barrier layer 230 comprises WN. In other embodiments, however, the metal-containing layer 225 and metal nitride barrier layer 230 comprise different refractory metals. E.g., when the metal-containing layer 225 comprises W or WSi, the metal nitride barrier layer 230 comprises TaN or TiN. In some case TaN is preferred over TiN because of the former's greater resistance to post-metal gate cleaning processes.

In some embodiments, to facilitate providing a dual work function CMOS device 710, the metal-containing layer 225 of the at least one transistor 202 (configured as an pMOS transistor) consists essentially of tungsten, and a metal-containing layer 770 of another one of the transistors 705 (configured as an nMOS transistor) consists essentially of tungsten silicide. E.g., there are less than about 10 atom percent of elements other than tungsten in the metal-containing layer 225 and less than about 10 atom percent of elements other than tungsten and silicon in the other metal-containing layer 770. In some embodiments the PMOS transistor 202 has a work function that ranges from about 4.8 to 5.0 eV, the nMOS transistor 705 has a work function that ranges from about 4.0 to 4.2 eV.

Those skilled in the art to which the disclosure relates will appreciate that other and further additions, deletions, substitutions, and modifications may be made to the described example embodiments, without departing from the disclosure.

1. A method of manufacturing a semiconductor device, comprising:
forming a gate stack layer, said gate stack having an insulating layer on a substrate, a metal-containing layer on said insulating layer, a metal nitride barrier layer on said metal-containing layer, and a silicon-containing layer on said metal nitride barrier layer; and
patterning said gate stack layer, includes a plasma etch of said metal nitride barrier layer said plasma etch having a chloride-containing feed gas and a physical etch component, wherein said physical etch component includes a high-mass species having a molecular weight of greater than about 71 gm/mol.

2. The method of claim 1, wherein said physical etch component consists essentially of said high-mass species.

3. The method of claim 1, wherein said high-mass species has a molecular weight ranging from about 81 to 117 gm/mol.

4. The method of claim 1, wherein said chloride-containing feed gas and said physical etch component are both BCl₃.

5. The method of claim 1, wherein said chloride-containing feed gas includes Cl₂ and said physical etch component includes HBr.

6. The method of claim 1, wherein a top horizontal length of said patterned metal nitride barrier layer is within about 10 percent of a bottom horizontal length of said patterned metal nitride barrier layer.

7. The method of claim 1, wherein a metal oxide layer is formed on a top surface of said metal nitride barrier layer during a silicon plasma etch of said silicon containing layer.

8. A method of manufacturing a semiconductor device, comprising: forming a gate stack layer, said gate stack having an insulating layer on a substrate, a metal-containing layer on said insulating layer, a metal nitride barrier layer on said metal-containing layer, and a silicon-containing layer on said metal nitride barrier layer; and
patterning said gate stack layer, includes a plasma etch of said metal nitride barrier layer said plasma etch having a chloride-containing feed gas and a physical etch component, wherein said physical etch component includes a high-mass species having a molecular weight of greater than about 71 am/mol, wherein said plasma etch process removes said metal nitride barrier layer by said plasma at least about 10 times faster than said metal layer.

9. The method of claim 1, wherein vertical walls of said patterned metal nitride barrier layer after said plasma etch are substantially free of metal chloride.

10. The method of claim 1, wherein said plasma etch process uniformly removes said metal nitride barrier layer, such that a surface roughness of said metal-containing layer during or immediately after said plasma etch process is about 2 nm or less.

11. A method of manufacturing a semiconductor device, comprising:
forming one or more transistors on or in a semiconductor substrate, wherein at least one of said transistors has a gate that is manufactured by a process including:
depositing an insulating layer on said substrate;
depositing a tungsten-containing layer on said insulating layer;
depositing refractory metal-containing nitride barrier layer on said tungsten-containing layer;
depositing a polysilicon layer on said tungsten-containing nitride layer; and
patterning said tungsten-containing metal nitride layer, including etching said tungsten-containing metal nitride layer using a plasma etch process having a BCl₃ or Cl₂ and HBr.

12. The method of claim 11, wherein said insulating layer includes silicon dioxide or a high k-dielectric.

13. The method of claim 11, wherein said tungsten-containing layer includes tungsten or tungsten silicide.

14. The method of claim 11, wherein said refractory metal-containing nitride barrier layer includes tantalum nitride or titanium nitride.

15. The method of claim 11, wherein said plasma etch process includes a feed gas of about 40 to 60 sccm BCl₃, a substrate temperature of about 50 to 80° C., a pressure of about 3 to 7 mTorr, and an RF-power of about 900 to 1200 Watts and a duration of about 10 to 20 seconds.

16-20. (canceled)

21. The method of claim 1, wherein said chloride-containing feed gas and said physical etch component consist essentially of BCl₃.

22. A method of manufacturing a semiconductor device, comprising:
forming one or more transistors on or in a semiconductor substrate, wherein at least one of said transistors has a gate that is manufactured by a process including:
depositing an insulating layer on said substrate;
depositing a tungsten-containing layer on said insulating layer;
depositing refractory metal-containing nitride barrier layer on said tungsten-containing layer;
depositing a polysilicon layer on said tungsten-containing nitride layer; and
patterning said tungsten-containing metal nitride layer, including etching said tungsten-containing metal nitride layer using a plasma etch process having a BCl₃ or Cl₂ and HBr, wherein said plasma etch process removes said metal nitride barrier layer by said plasma at least about 10 times faster than said metal layer.
